(19) United States
(12) Patent Application Publication
(10) Pub. No.: US 2026/0190940 A1
(43) Pub. Date: Jul. 2, 2026

(54) SUBSTRATE SUPPORT UNIT AND SUBSTRATE PROCESSING APPARATUS

(71) Applicant: SEMES CO., LTD., Cheonan-si (KR)

(72) Inventor: Seung Jun BAIK, Cheonan-si (KR)

(73) Assignee: SEMES CO., LTD., Cheonan-si (KR)

(21) Appl. No.: 19/430,012

(22) Filed: Dec. 22, 2025

(30) Foreign Application Priority Data
Dec. 30, 2024 (KR) 10-2024-0200786

(51) Int. Cl. H10P 72/72; H01J 37/32

(52) U.S. Cl. CPC H10P 72/722; H01J 37/32724; H01J 2237/002; H01J 2237/0206; H01J 2237/334

(57) ABSTRACT

Disclosed is a substrate support unit capable of addressing problems caused by floating charges accumulated therein. The substrate support unit includes an adsorption plate configured to adsorb and support a substrate disposed on an upper surface thereof and provided therein with a heater assembly configured to heat the substrate, a cooling plate disposed below the adsorption plate and provided therein with a coolant channel configured to allow a coolant to circulate therethrough, an electric circuit board electrically connected to the heater assembly and configured to control the heater assembly, and a discharge unit electrically connected to the electric circuit board via a discharge line connected to ground and including a protection module including surge protection components.

### CROSS-REFERENCE TO THE RELATED APPLICATION

The present application claims priority to and the benefit of Korean Patent Application No. 10-2024-0200786, filed on Dec. 30, 2024, in the Korean Intellectual Property Office, the entire disclosure of which is incorporated herein by reference.

### BACKGROUND

### 1. Field

The present disclosure relates to a substrate support unit and a substrate processing apparatus.

### 2. Description of the Related Art

A substrate processing apparatus is generally used to perform plasma processing operation on a substrate such as a semiconductor wafer in order to manufacture a semiconductor device. The plasma processing operation includes a deposition process of forming a predetermined film on a substrate surface, an etching process of forming a predetermined pattern on the film formed on the substrate, and a cleaning process of physically or chemically cleaning the substrate surface. The substrate processing operation is performed with the substrate supported on a substrate support unit. The substrate support unit includes a heater assembly configured to heat the substrate to a predetermined process temperature. To improve processing uniformity over an entire area of the substrate, the heater assembly typically includes a plurality of heater elements in order to independently control heating of respective regions of the substrate. In this case, the substrate support unit is provided with an electric circuit configured to supply power from a heater power supply to a specific heater element. The electric circuit includes a plurality of electrical components, such as switches configured to select a heater element to which heating power is to be applied and diodes configured to prevent reverse current.

In addition, one or more radio-frequency (RF) power supplies configured to apply bias voltage to a plasma generating unit and/or the substrate are connected to the substrate support unit. However, RF power supplied from the RF power supplies may cause interference in a heater power supply configured to supply power to the heater assembly. In order to address this problem, a technique of mounting an RF filter at a front end of the heater power supply has been proposed.

The substrate support unit may be provided with a coolant channel through which a coolant for cooling the substrate circulates. Floating charges may be accumulated in the substrate support unit by the circulating coolant flow. The accumulated floating charges may generate static electricity, which may cause arcing or sparking and may damage electrical components included in an electric circuit mounted in the substrate support unit. However, conventional techniques of mounting an RF filter fail to provide a solution to the problem of damage to electrical components caused by accumulation of floating charges.

Therefore, there is a need for a technique to address a problem caused by floating charges accumulated in a substrate support unit.

### RELATED ART DOCUMENT

### Patent Document

(Patent Document 1) U.S. Pat. No. 8,742,666 B2 (Jun. 3, 2014)

### SUMMARY

The present disclosure is directed to providing a substrate support unit and a substrate processing apparatus capable of addressing a problem caused by floating charges accumulated in a substrate support unit. In particular, the present disclosure is directed to addressing a problem in which electrical components included in an electric circuit board mounted in the substrate support unit are damaged by floating charges accumulated in the substrate support unit.

In addition, the present disclosure is directed to providing a substrate support unit and a substrate processing apparatus that not only address problems caused by floating charges accumulated in the substrate support unit but also minimize leakage of radio-frequency (RF) power applied to the substrate support unit.

A substrate support unit according to an embodiment of the present disclosure includes an adsorption plate configured to adsorb and support a substrate disposed on an upper surface thereof, the adsorption plate being provided therein with a heater assembly configured to heat the substrate, a cooling plate disposed below the adsorption plate, the cooling plate being provided therein with a coolant channel configured to allow a coolant to circulate therethrough, an electric circuit board electrically connected to the heater assembly, the electric circuit board being configured to control the heater assembly, and a discharge unit electrically connected to the electric circuit board via a discharge line connected to ground, the discharge unit including a protection module including surge protection components.

A substrate processing apparatus according to an embodiment of the present disclosure includes a chamber having a processing space defined therein to perform plasma processing on a substrate, a plasma generating unit configured to generate plasma in the processing space, a gas supply unit configured to supply gas to the processing space, and a substrate support unit disposed in the chamber, the substrate support unit being configured to adsorb and support the substrate, wherein the substrate support unit includes a heater assembly including a plurality of heater elements, a bias electrode configured to receive bias power of a first frequency from a bias power supply, an electric circuit board electrically connected to the heater assembly, the electric circuit board being configured to control the heater assembly, and a discharge unit including a discharge line connected between ground and the electric circuit board and a protection module including surge protection components mounted on the discharge line.

A substrate support unit according to an embodiment of the present disclosure includes an adsorption plate provided therein with a chuck electrode configured to provide electrostatic adsorption force to a substrate supported on an upper surface thereof, a bias electrode configured to receive bias power of a first frequency, and a heater assembly including a plurality of heater elements, a cooling plate disposed below the adsorption plate, the cooling plate being provided therein with a coolant channel configured to allow a coolant to circulate therethrough, an insulating plate disposed below the cooling plate, the insulating plate defining a mounting space between the insulating plate and the cooling plate, an electric circuit board mounted in the mounting space so as to be electrically connected to the heater assembly, the electric circuit board including a switch module including switches configured to selectively supply heater power to the plurality of heater elements and a switching diode module including switching diodes disposed between the switch module and the plurality of heater elements and configured to prevent reverse current, and a discharge unit including a discharge line connecting points between the switching diodes and the plurality of heater elements to ground and a protection module including surge protection components mounted on the discharge line.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIGS. 1A and 1B are schematic views of a substrate processing apparatus according to an embodiment of the present disclosure;

FIG. 2 is a diagram for explaining a substrate support unit according to an embodiment of the present disclosure;

FIG. 3 is a view for explaining a phenomenon in which floating charges are accumulated in a conventional substrate support unit;

FIG. 4 is a view for explaining a principle in which floating charges are removed in the substrate support unit according to an embodiment of the present disclosure; and

FIG. 5 is a diagram for explaining a substrate support unit according to another embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

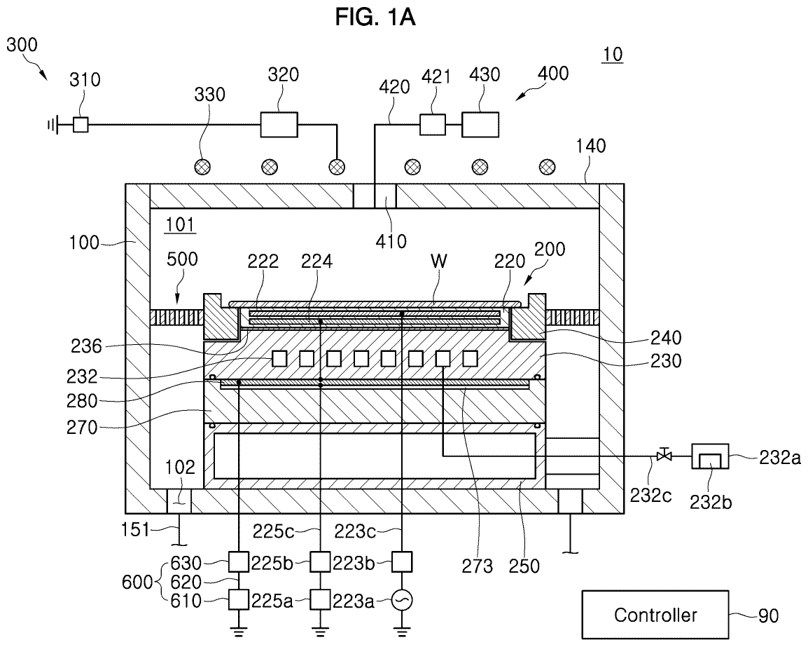

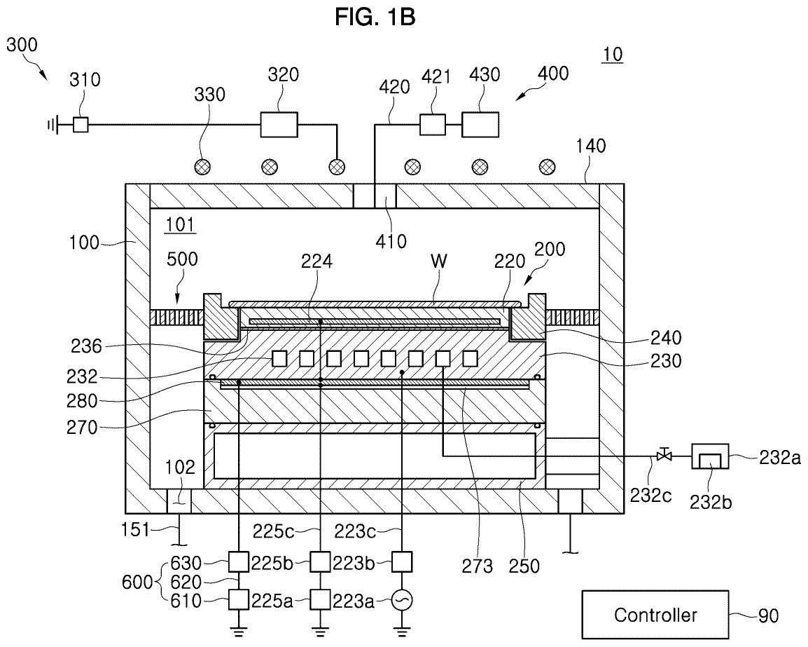

FIG. 1A is a schematic view of a substrate processing apparatus according to an embodiment of the present disclosure. A substrate processing apparatus 10 according to an embodiment of the present disclosure is an apparatus that processes a substrate W using plasma. For example, the substrate processing apparatus 10 may be an etching apparatus that etches a substrate using inductively coupled plasma (ICP). The substrate W may be a semiconductor wafer.

Referring to FIG. 1A, the substrate processing apparatus 10 according to an embodiment of the present disclosure may include a chamber 100, a substrate support unit 200, a plasma generating unit 300, a gas supply unit 400, a baffle unit 500, and a controller 90.

The chamber 100 has a processing space 101 defined therein, and substrate processing operation is performed in the processing space 101. The chamber 100 may be formed of a metallic material (e.g., aluminum), and may have an open top. The open top of the chamber 100 may be sealed by a window 140. An exhaust port 102, which is connected to a vacuum pump (not shown) via an exhaust pipe 151, may be formed in the bottom surface of the chamber 100.

The window 140 may be provided at an upper side of the chamber 100, and may be formed in a plate shape. The window 140 may cover an open top surface of the chamber 100 to seal the processing space 101. The window 140 may be formed of a dielectric material such as quartz.

The plasma generating unit 300 configured to generate plasma in the processing space 101 may be disposed above the chamber 100. The plasma generating unit 300 may include a radio-frequency (RF) power supply 310, a matcher 320, and an antenna 330. The RF power supply 310 is connected to the antenna 330 via the matcher 320. The RF power supply 310 may apply RF power in a range of several MHz to several tens of MHz to the antenna 330, thereby inducing a magnetic field in the processing space 101 to generate inductively coupled plasma. The window 140 may be formed of a dielectric such as quartz to allow the magnetic field to penetrate into the processing space 101.

The antenna 330 may include a coil member. The coil member may include a plurality of unit coils. The plurality of unit coils may be spiral coils and may be disposed to be spaced apart in an upward-downward direction. The antenna 330 may include an inner coil member and an outer coil member. The antenna 330 may be formed in various other structures.

Although the plasma generating unit 300 is illustrated in FIG. 1A as including a single RF power supply 310, the present disclosure is not limited thereto. When the antenna 330 includes a plurality of coil members such as an inner coil member and an outer coil member, the plasma generating unit 300 may include a plurality of RF power supplies configured to independently supply RF power to the respective coil members.

Although inductively coupled plasma is illustrated in FIG. 1A as an example, various types of plasma, such as capacitively coupled plasma (CCP), microwave plasma, and remote plasma, may be generated. That is, the plasma generating unit 300 of the present disclosure is not limited to any specific plasma source.

The gas supply unit 400 is configured to supply a process gas to the processing space 101. The gas supply unit 400 may include a gas source 430, a gas supply pipe 420, and a flow controller 421. The process gas may be selected according to the substrate processing operation. The process gas may be an etching gas. The process gas may include a gas containing a halogen element such as fluorine (F), chlorine (Cl), or bromine (Br). For example, the process gas may include at least one of F₂, Cl₂, HF, HBr, SF₆, NF₃, or CxFy (x and y being natural numbers). In addition, the process gas may include H₂, O₂, and/or an inert gas.

The flow controller 421 may include a mass flow controller (MFC) and/or an on-off valve.

The gas supply pipe 420 may be connected to a nozzle 410 mounted through a central portion of the window 140. The process gas supplied from the gas source may be supplied to the processing space 101 through the nozzle 410, and plasma of the process gas may be generated in the processing space 101 by RF power supplied from the plasma generating unit 300.

Although one gas source 430, one gas supply pipe 420, and one flow controller 421 are illustrated in FIG. 1A, the gas supply unit 400 of the present disclosure may include a plurality of gas sources configured to supply a plurality of gases to the processing space 101 and a plurality of flow controllers configured to independently control supply of the respective gases.

Although the process gas is illustrated in FIG. 1A as being supplied to the processing space 101 through the nozzle 410 mounted through the window 140, the present disclosure is not limited thereto. The process gas may be supplied through a nozzle mounted through a sidewall of the chamber 100.

The substrate support unit 200 configured to adsorb and support the substrate W is provided inside the chamber 100. The substrate support unit 200 may include an adsorption plate 220, a cooling plate 230, a base plate 250, an insulating plate 270, an electric circuit board 280, and a discharge unit 600.

The adsorption plate 220 may be a disc-shaped dielectric and may support the substrate W disposed on an upper surface thereof. The adsorption plate 220 may be provided therein with a chuck electrode (not shown) to provide electrostatic adsorption force to the substrate W. However, the present disclosure is not limited thereto. The substrate support unit 200 may adsorb the substrate W in various other manners such as vacuum adsorption or mechanical clamping. Alternatively, the substrate support unit 200 may not provide separate adsorption force to the substrate W.

The adsorption plate 220 is provided therein with a bias electrode 222. The bias electrode 222 is connected to a bias power supply 223a via a bias supply line 223c. Bias power supplied from the bias power supply 223a is applied to the bias electrode 222. The bias power supply 223a may apply RF power in a frequency range of several hundred kHz to several tens of MHz. The bias power may control a velocity and/or an angle of incidence of ions in plasma on the substrate W. A matcher 223b for impedance matching may be disposed between the bias power supply 223a and the bias electrode 222. Although one bias power supply 223a is illustrated in FIG. 1A, a plurality of bias power supplies having different frequencies may be included.

The adsorption plate 220 is provided therein with a heater assembly 224 configured to heat the substrate W. The heater assembly 224 may be located below the bias electrode 222. The heater assembly 224 is connected to a heater power supply 225a via a heater power line 225c. The heater power supply 225a may be a direct-current (DC) or alternating-current (AC) power supply. In some cases, the heater power supply 225a may include both a DC power supply and an AC power supply. The heater assembly 224 may be a resistive heater configured to generate heat by resisting current supplied from the heater power supply 225a. The generated heat may be transferred to the substrate W through the adsorption plate 220. An RF filter unit 225b may be mounted on the heater power line 225c that connects the heater power supply 225a to the heater assembly 224. The RF filter unit 225b may include a frequency blocking filter configured to block a frequency of bias power so that RF power supplied from the bias power supply 223a does not cause interference in the heater power supply 225a. The RF filter unit 225b may include a low-pass filter configured to pass a frequency equal to or lower than the frequency of the bias power.

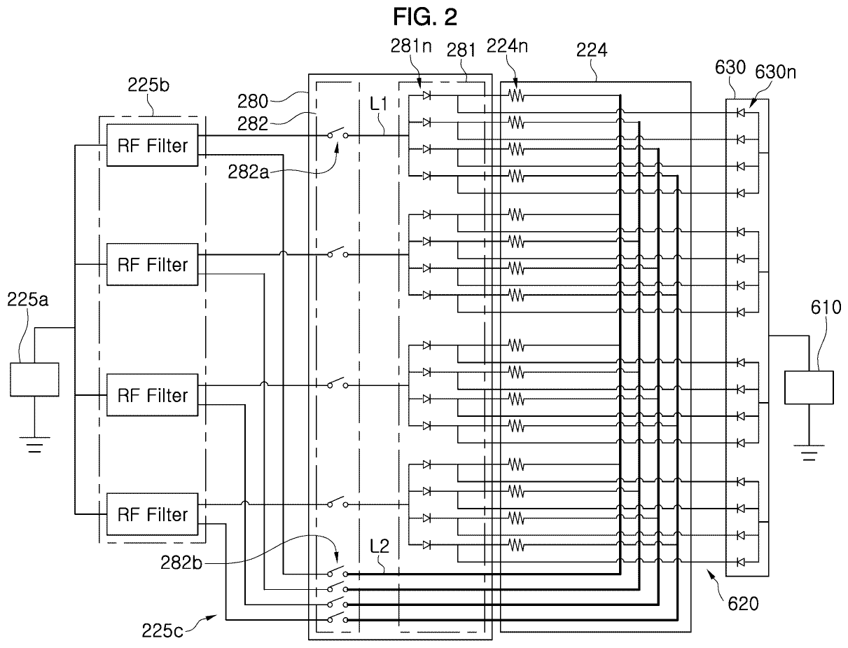

The heater assembly 224 may be configured as a plurality of separated zone heaters in order to independently control the temperatures of respective regions of the substrate W. To this end, the heater assembly 224 may include a plurality of heater elements. The plurality of heater elements may be disposed in various array structures such as a concentric shape or a matrix shape, and may heat regions of the substrate W corresponding to the respective heater elements. The plurality of heater elements may each be a coil heater having a spiral shape and may be electrically connected to each other. The plurality of heater elements may cover an entire area of the substrate W. The plurality of heater elements may be independently controlled for heating. Time intervals during which the plurality of heater elements operates to heat the substrate may be the same as or different from each other, or may partially overlap each other. That is, during a certain time interval, only some of the plurality of heater elements may be connected to the heater power supply 225a and may heat the substrate. The configuration of an electric circuit for selectively operating the heater elements will be described later with reference to FIG. 2.

The cooling plate 230 may be disposed below the adsorption plate 220. The adsorption plate 220 and the cooling plate 230 may be bonded to each other using an adhesive layer 236. The cooling plate 230 may be formed of a metal such as aluminum. An upper surface of the cooling plate 230 may be stepped such that a central region thereof is positioned higher than an edge region thereof. The central region of the upper surface of the cooling plate 230 may have an area corresponding to a lower surface of the adsorption plate 220 and may be bonded to the lower surface of the adsorption plate 220. A ring member 240 may be provided on a stepped outer peripheral surface of the cooling plate 230. The ring member 240 may be provided to surround a circumference of the adsorption plate 220. The ring member 240 may include a focus ring. An edge region of the substrate W may extend outward beyond the adsorption plate 220 and may be supported by the ring member 240.

The cooling plate 230 may be provided therein with a coolant channel 232, which serves as a passage through which a coolant circulates. The coolant channel 232 may be formed in a spiral shape inside the cooling plate 230. Alternatively, the coolant channel 232 may include ring-shaped channels disposed concentrically with each other and having different radii. In this case, the coolant channels 232 may be in communication with each other. The coolant channels 232 may be formed at the same height.

The coolant channel 232 may be connected to a coolant source 232a via a coolant supply pipe 232c. The coolant source 232a may store a coolant. A cooler 232b may be provided inside the coolant source 232a. The cooler 232b may cool the coolant to a predetermined temperature. Alternatively, the cooler 232b may be mounted on the coolant supply pipe 232c. The coolant supplied to the coolant channel 232 via the coolant supply pipe 232c may circulate along the coolant channel 232 and may cool the cooling plate 230. As the cooling plate 230 is cooled, the adsorption plate 220 and the wafer W may also be cooled.

The base plate 250 may be located at a lower end portion of the substrate support unit 200. The base plate 250 may be located on the bottom surface of the chamber 100 or may be spaced upward from the bottom surface of the chamber 100. A base space 255 may be defined inside the base plate 250. The base space 255 may be a space communicating with outside air. An outer radius of the base plate 250 may be set to be equal to an outer radius of the cooling plate 230. A lift pin module (not shown) configured to support and vertically move the substrate W may be located in the base space 255. The base plate 250 may be formed of a metal.

The insulating plate 270 may be located between the cooling plate 230 and the base plate 250. The insulating plate 270 may cover an upper surface of the base plate 250. The insulating plate 270 may be formed to have a cross-sectional area corresponding to that of the cooling plate 230. The insulating plate 270 may include an insulator. The insulating plate 270 may serve to increase an electrical distance between the cooling plate 230 and the base plate 250, thereby allowing the cooling plate 230 to be in an electrically floating state.

The baffle unit 500 may be located between an inner sidewall of the chamber 100 and the substrate support unit 200. The baffle unit 500 may be formed in a ring shape. The baffle unit 500 may include a plurality of through-holes formed therein, and a process gas provided in the chamber 100 may pass through the through-holes in the baffle unit 500 and may be exhausted through the exhaust port 102. A flow of the process gas may be controlled according to the shape of the baffle unit 500 and the shape of the through-holes.

The controller 90 controls operation of the substrate processing apparatus 10. The controller 90 may include a central processing unit (CPU), memory, and circuits. The CPU may be one of any form of a general-purpose processor. The memory may be random access memory (RAM), read only memory (ROM), a floppy disk, a hard disk, or any other form of digital storage, local or remote. The memory may store a process recipe for performing substrate processing using the substrate processing apparatus.

The substrate support unit 200 includes an electric circuit board 280 configured to control the heater assembly 224. The electric circuit board 280 may be disposed between the cooling plate 230 and the insulating plate 270. A mounting space 273 for mounting the electric circuit board 280 may be defined between the cooling plate 230 and the insulating plate 270. For example, the insulating plate 270 may include a stepped portion formed on an edge region of an upper surface thereof so as to protrude upward. Accordingly, a recess may be formed in a central region of the upper surface of the insulating plate 270 due to the stepped portion, and the mounting space 273 may be defined by the recess. Alternatively, the cooling plate 230 may include a stepped portion formed on an edge region of a lower surface thereof so as to protrude downward, and the mounting space 273 may be defined by the stepped portion. It is to be understood that the mounting space 273 generally refers to a spacing formed between the insulating plate 270 and the cooling plate 230. The present disclosure is not limited to any specific shape or structure of the mounting space 273. Outer peripheral portions of the insulating plate 270 and the cooling plate 230 may be sealed by a sealing member, so that the mounting space 273 may be isolated from the processing space 101. However, the present disclosure is not limited to a configuration in which the electric circuit board 280 is mounted between the cooling plate 230 and the insulating plate 270.

The electric circuit board 280 may be electrically connected to the heater assembly 224 and the heater power supply 225a. The heater power line 225c may electrically connect the heater power supply 225a, the RF filter unit 225b, the electric circuit board 280, and the heater assembly 224 to each other. The heater power line 225c may include a line connecting the heater power supply 225a to the electric circuit board 280 and a line connecting the electric circuit board 280 to the heater assembly 224. The heater power line 225c does not refer to a single electric line, and may include a plurality of lines.

The discharge unit 600 is included in the substrate support unit 200 and is configured to prevent electronic components in the electric circuit board 280 from being damaged by floating charges accumulated in the cooling plate 230. When the floating charges accumulated in the cooling plate 230 exceed a predetermined level, the discharge unit 600 releases the floating charges through a discharge line 620, thereby preventing electronic components included in the electric circuit board 280 from being exposed to overvoltage. To this end, the discharge unit 600 includes a protection module 630 mounted on the discharge line 620. The protection module 630 may include a surge protection component that maintains high resistance during normal operation so as not to affect operation of the electric circuit board 280 and discharges current from the electric circuit board 280 to ground when overvoltage exceeding a predetermined level occurs. For example, the protection module 630 may include a transient voltage suppressor (TVS) diode.

The discharge unit 600 may include a ground filter 610 in order to prevent RF power supplied from the bias power supply 223a from leaking through the discharge line 620. The ground filter 610 may be mounted on the discharge line 620 and may be disposed between the protection module 630 and ground. The ground filter 610 may include a frequency blocking filter configured to block the frequency of the bias power. The ground filter 610 may include a low-pass filter configured to pass a frequency equal to or lower than the frequency of the bias power.

Although the protection module 630 is illustrated in FIG. 1A as being separately provided from the electric circuit board 280 and connected to the electric circuit board 280, the protection module 630 may be integrated into the electric circuit board 280. In addition, although the ground filter 610 is illustrated in FIG. 1A as being separately provided from the RF filter unit 225b, the ground filter 610 and the RF filter unit 225b may be disposed inside a single filter module and may share the same ground.

Although the bias electrode 222 is illustrated in FIG. 1A as being included in the adsorption plate 220, the bias electrode 222 may be omitted from the adsorption plate 220. Referring to FIG. 1B, the cooling plate 230 may serve as the bias electrode and may be connected to the bias power supply 223a via the bias supply line 223c. The bias power supply 223a may apply RF power in a frequency range of several hundred KHz to several tens of MHz to the adsorption plate 220.

FIG. 2 is a diagram for explaining a substrate support unit according to an embodiment of the present disclosure, in which the protection module 630 is separately provided from the electric circuit board 280. FIG. 2 illustrates a configuration in which sixteen heater elements 224n are included in the heater assembly 224. However, the number of heater elements 224n may be varied as needed. The number of heater elements 224n may be one hundred or greater. The heater elements 224n may be disposed to control heating of respective regions of the substrate W, and may be disposed in various array structures such as a matrix shape or a concentric shape.

The heater assembly 224 is electrically connected to the electric circuit board 280. The electric circuit board 280 may include a switching circuit configured to connect a plurality of heater elements to the heater power supply 225a. To this end, the electric circuit board 280 may include a switch module 282 including a plurality of switches.

The switch module 282 includes a plurality of first switches 282a disposed on first lines L1, which are supply lines through which power is supplied to the heater elements 224n, and a plurality of second switches 282b disposed on second lines L2, which are return lines through which power having passed through the heater elements 224n returns. The number of first switches 282a and the number of second switches 282b may be determined depending on the total number of heater elements 224n and the number of heater elements 224n managed by each of the first switches 282a.

In the example shown in FIG. 2, the total number of heater elements 224n is sixteen, and each of the first switches 282a is responsible for four heater elements 224n. Accordingly, four first switches 282a and four second switches 282b are provided. The heater elements 224n may be provided in a number corresponding to a product of the number of first switches 282a and the number of second switches 282b (4×4=16).

The first line L1 passing through one first switch 282a may be branched into a plurality of branch lines, and one heater element 224n may be disposed on each branch line. In the example shown in FIG. 2, the first line L1 passing through one first switch 282a is branched into four branch lines. In addition, the heater elements 224n on the respective branch lines may be connected to the second switches 282b via different second lines L2. For example, the heater element disposed on the first branch line (the uppermost branch line) among the four branch lines branched from the 1-1^{st} switch (the uppermost one of the four first switches in FIG. 2) may be connected to the 2-1^{st} switch (the uppermost one of the four second switches in FIG. 2) via the 2-1^{st} line (the uppermost one of the four second lines in FIG. 2). The heater element disposed on the second branch line may be connected to the 2-2^{nd} switch via the 2-2^{nd} line. The heater element disposed on the third branch line may be connected to the 2-3^{rd} switch via the 2-3^{rd} line. The heater element disposed on the fourth branch line may be connected to the 2-4th switch via the 2-4th line. The same arrangement structure as that described above may also be applied to the branch lines branched from the remaining first switches 282a. The heater element 224n to which heater power is to be supplied may be selected through combinations of the first switches 282a and the second switches 282b disposed as described above.

A switching diode module 281 including switching diodes 281n for preventing reverse current may be disposed between the first switches 282a and the heater elements 224n. The switching diodes 281n may be disposed to correspond one-to-one to the heater elements 224n on the respective branch lines branched from the first lines L1. The switching diode module 281 may be provided on the electric circuit board 280 as an integrated circuit together with the switch module 282.

The RF filter unit 225b disposed between the heater power supply and the electric circuit board 280 may include plurality of RF filters. Each of the RF filters may be connected to a respective one of the first switches 282a and a respective one of the second switches 282b. The number of RF filters included in the RF filter unit 225b may be equal to the number of first switches 282a and the number of second switches 282b (four in the example shown in FIG. 2).

Electronic components included in the electric circuit board 280, for example, the switching diodes 281n and/or the switches 282a and 282b, may be damaged by overvoltage caused by floating charges accumulated in the cooling plate 230. To prepare for overvoltage, it may be considered to use components having excellent withstand voltage characteristics for electronic components. However, components having excellent withstand voltage characteristics may be difficult to mount on the electric circuit board 280 due to relatively large sizes thereof. In particular, as the number of heater elements 224n included in the heater assembly 224 increases precise control of the temperature of the substrate W, more electronic components need to be mounted. Thus, due to the physical space limitations, it may be practically difficult to use electronic components having excellent withstand voltage characteristics.

To address such an issue, the present disclosure includes the discharge unit 600 that releases floating charges through the discharge line 620 when the floating charges accumulated in the cooling plate 230 exceed a predetermined level and cause overvoltage. Accordingly, it may be possible to prevent the electronic components included in the electric circuit board 280 from being exposed to overvoltage.

The discharge unit 600 includes a protection module 630 mounted on the discharge line 620 or connected to the discharge line 620. The protection module 630 includes a plurality of surge protection components 630n. In the embodiment of the present disclosure, the surge protection components 630n may be TVS diodes.

Each of the surge protection components 630n may be connected between a respective one of the switching diodes 281n and a respective one of the heater elements 224n via the discharge line 620. That is, a plurality of lines connected between the respective switching diodes 281n and the respective heater elements 224n may form the discharge line 620, and the surge protection components 630n may be disposed on the plurality of lines forming the discharge line 620. The number of surge protection components 630n may be equal to the number of switching diodes 281n. The number of surge protection components 630n may be equal to the number of heater elements 224n. Overcurrent having passed through the surge protection components 630n may be discharged to ground via the ground filter 610.

The surge protection components 630n maintain high resistance during normal operation so as not to affect operation of the electric circuit board 280, and when overvoltage exceeding a predetermined level occurs, the surge protection components 630n discharge overcurrent to ground, thereby protecting electronic components included in the electric circuit board 280. In particular, TVS diodes having a fast response speed may be suitable as the surge protection components 630n.

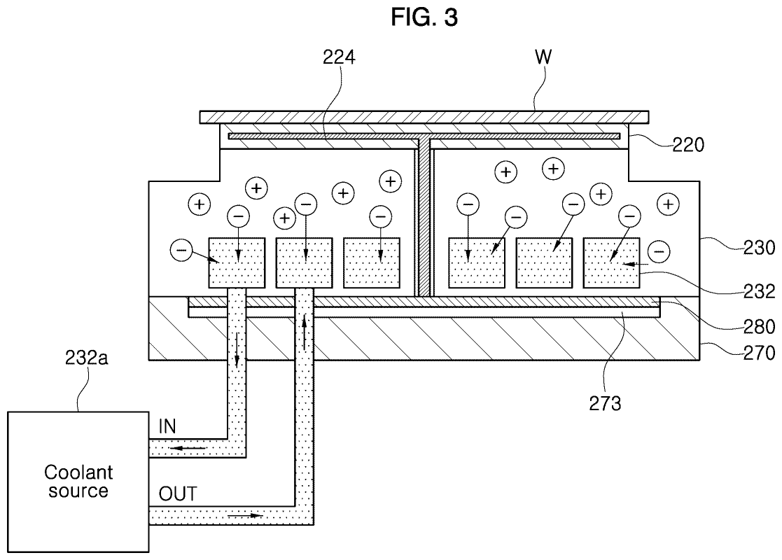

FIG. 3 is a view for explaining a phenomenon in which floating charges are accumulated in a conventional substrate support unit 200 without the discharge unit 600. As conceptually shown in FIG. 3, floating charges may be generated in the cooling plate 230 while a coolant circulates through the coolant channel 232 in the cooling plate 230. Because the cooling plate 230 is in a floating state, the floating charges are not dissipated but continue to accumulate, thereby affecting the electric circuit board 280. When voltage due to floating charges increases above a predetermined level, electronic components such as the switching diodes 281n included in the electric circuit board 280 may be damaged.

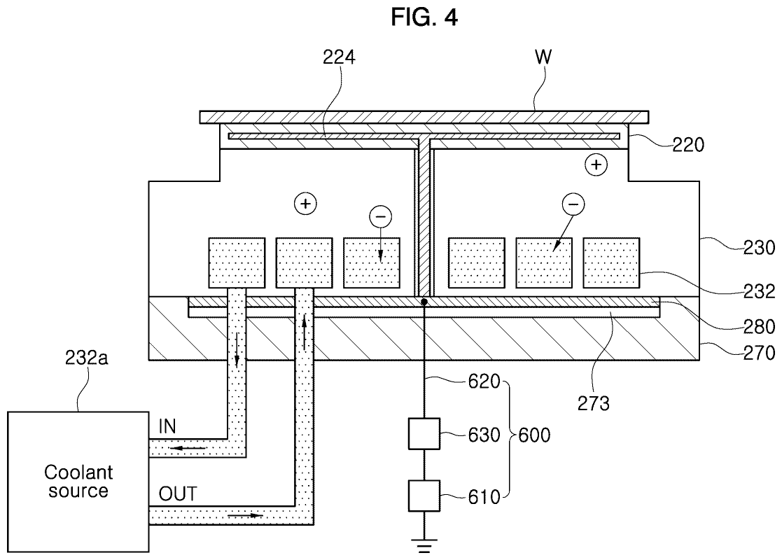

In contrast, as shown in FIG. 4, in the substrate support unit including the discharge unit 600 according to an embodiment of the present disclosure, overvoltage caused by floating charges generated in the cooling plate 230 may be discharged through the discharge unit 600 before affecting electronic components included in the electric circuit board 280. As a result, according to the present disclosure, it may be possible to prevent damage to electronic components included in the electric circuit board 280.

Table 1 below shows test results of the effect obtained by applying the discharge unit 600. In a state in which no substrate W was loaded on the substrate support unit 200, voltages to the upper surface of the substrate support unit 200 were measured after circulating a coolant through the coolant channel 232 for a predetermined time period. The voltages were measured using an electrostatic measuring device at four positions spaced at 90-degree intervals in the circumferential direction. TVS diodes were used as the surge protection components 630n included in the protection module 630 of the discharge unit 600.

TABLE 1

| Measurement | Before Application of | After Application of |
|---|---|---|
| Position | Discharge Unit (V) | Discharge Unit (V) |
| A | 2000 (Max) | 15 |
| B | 2000 (Max) | 44 |
| C | 2000 (Max) | 58 |
| D | 2000 (Max) | 10 |

As can be seen from the results in Table 1, before applying the discharge unit 600 as shown in FIG. 3, voltages exceeding 2000 V, which is the measurement limit of the measuring device, were measured at all measurement positions. This indicates that a large number of floating charges were generated in the substrate support unit 200 due to circulation of the coolant through the coolant channel 232.

In contrast, after applying the discharge unit 600 according to the embodiment of the present disclosure as shown in FIG. 4, greatly reduced voltages were measured at all measurement positions. This indicates that floating charges generated due to circulation of the coolant through the coolant channel 232 were effectively removed.

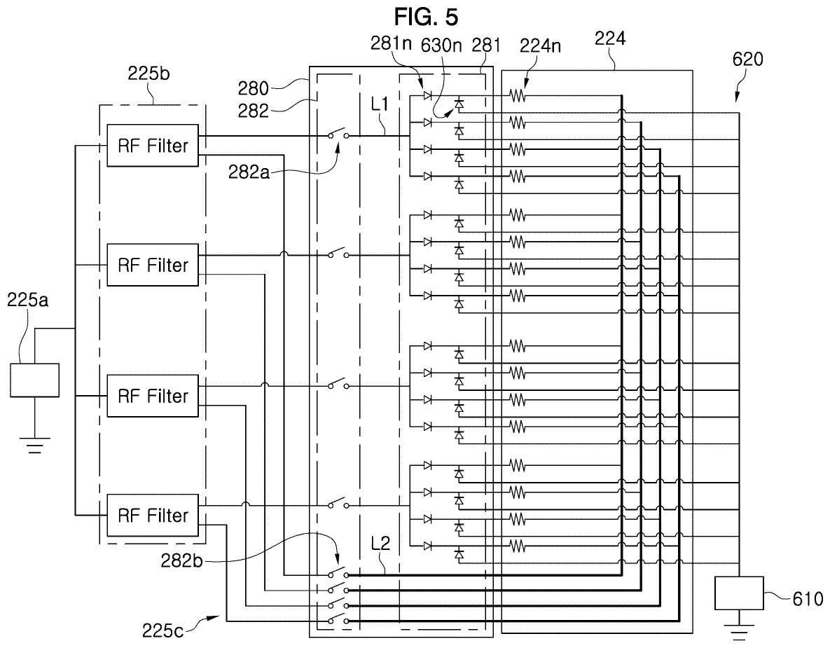

FIG. 5 is a diagram for explaining a substrate support unit according to another embodiment of the present disclosure, in which the protection module 630 is integrated into the electric circuit board 280. In the embodiment shown in FIG. 2, the protection module 630 is separately provided from the electric circuit board 280 and is electrically connected to the electric circuit board 280, whereas in the embodiment shown in FIG. 5, surge protection components 630n are disposed within the electric circuit board 280. The surge protection components 630n may be connected to the ground filter 610 disposed outside via the discharge line 620, and, as described above, the ground filter 610 is connected to ground. That is, a current path is implemented in the order of the surge protection components 630n, the discharge line 620, the ground filter 610, and ground. Accordingly, overvoltage caused by floating charges generated in the cooling plate 230 may be discharged through the above-described current path before affecting electronic components included in the electric circuit board 280. Except for the position of the protection module 630, the embodiment shown in FIG. 5 has the same configuration as the embodiment shown in FIG. 2.

As is apparent from the above description, according to an embodiment of the present disclosure, a discharge unit includes a protection module electrically connected to an electric circuit board for controlling a heater assembly and including surge protection components, thereby addressing issues caused by floating charges accumulated in a substrate support unit.

In addition, according to an embodiment of the present disclosure, a ground filter configured to block the frequency of RF power applied to the substrate support unit is disposed in the discharge unit, thereby not only addressing issues caused by floating charges accumulated in the substrate support unit, but also minimizing leakage of the RF power applied to the substrate support unit.

Although the exemplary embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A substrate support unit comprising:
an adsorption plate configured to adsorb and support a substrate disposed on an upper surface thereof, the adsorption plate being provided therein with a heater assembly configured to heat the substrate;
a cooling plate disposed below the adsorption plate, the cooling plate being provided therein with a coolant channel configured to allow a coolant to circulate therethrough;
an electric circuit board electrically connected to the heater assembly, the electric circuit board being configured to control the heater assembly; and
a discharge unit electrically connected to the electric circuit board via a discharge line connected to ground, the discharge unit comprising a protection module comprising surge protection components.

2. The substrate support unit as claimed in claim 1, wherein the surge protection components are transient voltage suppressor (TVS) diodes.

3. The substrate support unit as claimed in claim 1, further comprising a bias power supply configured to apply bias power of a first frequency to the cooling plate,
wherein a ground filter configured to block the first frequency is mounted on the discharge line.

4. The substrate support unit as claimed in claim 1, wherein the adsorption plate comprises a bias electrode, and
wherein the substrate support unit further comprises a bias power supply configured to apply bias power of a first frequency to the bias electrode.

5. The substrate support unit as claimed in claim 1, wherein the heater assembly comprises a plurality of heater elements and receives heating power from a heater power supply through a heater power line,
wherein the heater power line comprises a first line as a supply line for supply of power to the plurality of heater elements and a second line as a return line for return of power having passed through the plurality of heater elements, and
wherein the electric circuit board comprises a first switch disposed on the first line and a second switch disposed on the second line.

6. The substrate support unit as claimed in claim 5, further comprising a switching diode module comprising switching diodes disposed between the first switch and the plurality of heater elements.

7. The substrate support unit as claimed in claim 6, wherein the discharge line is connected between the plurality of heater elements and the switching diodes.

8. The substrate support unit as claimed in claim 7, wherein the plurality of heater elements, the switching diodes, and the surge protection components are provided in the same number.

9. The substrate support unit as claimed in claim 5, further comprising a bias power supply configured to apply bias power of a first frequency to the cooling plate,
wherein a radio-frequency (RF) filter unit configured to block the first frequency is mounted between the heater power supply and the electric circuit board.

10. The substrate support unit as claimed in claim 9, wherein a ground filter configured to block the first frequency is mounted on the discharge line, and
wherein the RF filter unit and the ground filter share ground.

11. The substrate support unit as claimed in claim 1, wherein the protection module is integrated into the electric circuit board.

12. The substrate support unit as claimed in claim 1, wherein an insulating plate is disposed below the cooling plate, and
wherein a mounting space for mounting of the electric circuit board is defined between the cooling plate and the insulating plate.

13. A substrate processing apparatus comprising:
a chamber having a processing space defined therein to perform plasma processing on a substrate;
a plasma generating unit configured to generate plasma in the processing space;
a gas supply unit configured to supply gas to the processing space; and
a substrate support unit disposed in the chamber, the substrate support unit being configured to adsorb and support the substrate,
wherein the substrate support unit comprises:
a heater assembly comprising a plurality of heater elements;
a bias electrode configured to receive bias power of a first frequency from a bias power supply;
an electric circuit board electrically connected to the heater assembly, the electric circuit board being configured to control the heater assembly; and
a discharge unit comprising a discharge line connected between ground and the electric circuit board and a protection module comprising surge protection components mounted on the discharge line.

14. The substrate processing apparatus as claimed in claim 13, wherein the surge protection components are TVS diodes.

15. The substrate processing apparatus as claimed in claim 13, wherein a ground filter configured to block the first frequency is mounted on the discharge line.

16. The substrate processing apparatus as claimed in claim 13, wherein the heater assembly receives heating power from a heater power supply through a heater power line,
wherein the heater power line comprises a first line as a supply line for supply of power to the plurality of heater elements and a second line as a return line for return of power having passed through the plurality of heater elements, and
wherein the electric circuit board comprises a switch module comprising a first switch disposed on the first line and a second switch disposed on the second line and a switching diode module comprising switching diodes disposed between the first switch and the plurality of heater elements.

17. The substrate processing apparatus as claimed in claim 16, wherein the discharge line is connected between the plurality of heater elements and the switching diodes.

18. A substrate support unit comprising:
an adsorption plate provided therein with a chuck electrode configured to provide electrostatic adsorption force to a substrate supported on an upper surface thereof and a heater assembly comprising a plurality of heater elements;
a cooling plate disposed below the adsorption plate, the cooling plate being provided therein with a coolant channel configured to allow a coolant to circulate therethrough, the cooling plate being configured to receive bias power of a first frequency;
an insulating plate disposed below the cooling plate, the insulating plate defining a mounting space between the insulating plate and the cooling plate;
an electric circuit board mounted in the mounting space so as to be electrically connected to the heater assembly, the electric circuit board comprising a switch module comprising switches configured to selectively supply heater power to the plurality of heater elements and a switching diode module comprising switching diodes disposed between the switch module and the plurality of heater elements and configured to prevent reverse current; and
a discharge unit comprising:
a discharge line connecting points between the switching diodes and the plurality of heater elements to ground, and
a protection module comprising surge protection components mounted on the discharge line.

19. The substrate support unit as claimed in claim 18, wherein the surge protection components are TVS diodes.

20. The substrate support unit as claimed in claim 18, wherein a ground filter configured to block the first frequency is mounted on the discharge line.
